(19) United States
(12) Patent Application Publication
(10) Pub. No.: US 2026/0190290 A1
(43) Pub. Date: Jul. 2, 2026

(54) ADAPTIVE MICROFLUIDIC PUMP THERMAL REGULATION SYSTEMS AND METHODS

(71) Applicant: Toyota Motor Engineering & Manufacturing North America, Inc., Plano, TX (US)

(72) Inventor: Shailesh Joshi, Ann Arbor, MI (US)

(73) Assignee: Toyota Motor Engineering & Manufacturing North America, Inc., Plano, TX (US)

(21) Appl. No.: 19/006,777

(22) Filed: Dec. 31, 2024

(51) Int. Cl. H05K 7/20

(52) U.S. Cl. CPC H05K 7/20327; H05K 7/20318; H05K 7/20381

(57) ABSTRACT

Embodiments of cooling assemblies for thermal management of one or more electronic devices include a fluid reservoir, a condenser, a housing including one or more substrates, a side wall, an upper wall positioned opposite of the substrates and spaced apart by the side wall to define a cavity, a plurality of fiber pump jets fluidly coupling the fluid reservoir to the housing, and one or more electric sources electrically coupled to one of the fiber pump jets. One or more of the fiber pump jets include one or more pairs of wire electrodes. The electric sources are configured to individually apply controllable biases to the wire electrodes of one or more fiber pump jets to control a flow rate of the dielectric liquid from the fluid reservoir to the cavity in the one or more fiber pump jets.

### TECHNICAL FIELD

The present specification generally relates to thermal regulation, and more particularly, related to using an adaptive microfluidic fiber pump to change a fluid flow rate of a manifold system.

### BACKGROUND

In thermal regulation systems, pumps are often used to drive fluid through channels, overcoming flow resistance and delivering a uniform flow across the entire system due to a single pressure source. However, external pumps and their required components—such as valves and reservoirs—add bulk and complexity, making it difficult to achieve localized control over fluid flow in each channel. This uniform flow approach limits cooling efficiency, as it cannot adapt to varying thermal loads in different channels. Consequently, there is a need for improved the thermal regulation systems.

### SUMMARY

In one embodiment, a cooling assembly for thermal management of one or more electronic devices, includes a fluid reservoir, a condenser, a housing including one or more substrates, a side wall, an upper wall positioned opposite of the substrates and spaced apart by the side wall to define a cavity, a plurality of fiber pump jets fluidly coupling the fluid reservoir to the housing, and one or more electric sources electrically coupled to one of the fiber pump jets. One or more of the fiber pump jets include one or more pairs of wire electrodes. The electric sources are configured to individually apply controllable biases to the wire electrodes of one or more fiber pump jets to control a flow rate of the dielectric liquid from the fluid reservoir to the cavity in the one or more fiber pump jets.

In another embodiment, a cooling system for thermal management of one or more electronic devices, includes a fluid reservoir configured to store a dielectric liquid, a condenser fluidly coupled to the fluid reservoir, a housing including one or more substrates, a side wall, an upper wall positioned opposite of the substrates and spaced apart by the side wall to define a cavity, the cavity fluidly coupled to the condenser and one or more of the substrate configured to be thermally coupled to one or more of the electronic devices, a plurality of fiber pump jets fluidly coupling the fluid reservoir to the housing, one or more of the fiber pump jets including one or more pairs of wire electrodes, one or more electric sources, one or more of the electric sources electrically coupled to one of the fiber pump jets, one or more thermal sensors configured to monitor temperatures of the electronic devices,, and one or more processors, the processors operable to, based on the temperatures of the electronic devices, control a flow rate of the dielectric liquid from the fluid reservoir to the cavity in the one or more of the fiber pump jets by controlling a bias applied to the wire electrodes of the one or more of the fiber pump jets.

In a third embodiments, a method for thermal management of one or more electronic devices, includes detecting, using one or more thermal sensors, temperatures of the one or more electronic devices, determining whether a temperature of at least one electronic device is beyond a cooling threshold temperature, in response to determining that the temperature of the at least one electronic device is beyond the cooling threshold temperature, controlling a bias applied to a pair of wire electrodes of a fiber pump jet associated with the at least one electronic device to transport a dielectric liquid from a fluid reservoir to a cavity of a housing comprising a substrate thermally coupled to the at least one electronic device. The fluid reservoir is fluidly coupled to a condenser, the housing includes one or more substrates, a side wall, an upper wall positioned opposite of the substrates and spaced apart by the side wall to define the cavity. The cavity is fluidly coupled to the condenser. One or more of the substrates are thermally coupled to one of the electronic devices. A plurality of fiber pump jets are fluidly coupling the fluid reservoir to the housing, one or more of the fiber pump jets comprising one or more pairs of wire electrodes. One or more electrically coupled to one of the fiber pump jets.

These and additional features provided by the embodiments described herein will be more fully understood in view of the following detailed description, in conjunction with the drawings.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1A schematically depicts a cross sectional perspective view of an example adaptive microfluidic pump thermal regulation system according to one or more embodiments shown and described herein;

FIG. 1B schematically depicts a top perspective view of the example adaptive microfluidic pump thermal regulation system of FIG. 1A according to one or more embodiments shown and described herein;

FIG. 1C schematically depicts an example fiber pump jet according to one or more embodiments shown and described herein;

FIG. 1D schematically depicts a perspective cross sectional view of the example adaptive microfluidic pump thermal regulation system in a two-phase cooling mode according to one or more embodiments shown and described herein;

FIG. 2 schematically depicts non-limiting components of the adaptive microfluidic pump thermal regulation system according to one or more embodiments shown and described herein; and

FIG. 3 illustrates a flow diagram of illustrative steps for thermal management of one or more electronic devices according to one or more embodiments shown and described herein.

### DETAILED DESCRIPTION

Embodiments of the present disclosure are directed to thermal regulation systems that can individually modulate the cooling flow based on heat load locally and therefore provide cooling on-demand while saving pumping power. The thermal regulation systems of the present disclosure may include a microfluidic fiber pump and be configured to individually control a flow rate inside a cooler assembly. The microfluidic fiber pump may include electrodes exposed along the inner surface of a pump tube wall for electrohydrodynamic (EHD) pumping. The thermal regulation systems can be further switched between a one-phase cooling mode and a two-phase cooling mode.

Pumps are commonly employed in capillary-based thermal regulation systems to drive fluid through the assembly and counteract flow resistance as the fluid moves through various channels. In such setups, external pumps provide the necessary pressure to push the coolant across the system. However, since these pumps supply a single pressure source, they deliver a uniform flow rate throughout the entire system without the ability to vary flow between individual channels. This uniform flow approach means that each channel receives the same amount of coolant, regardless of specific cooling requirements in different areas, which can be a limitation in systems where certain channels experience higher thermal loads than others.

Moreover, external pumps often require additional components, such as valves, reservoirs, and tubing, to manage and direct the flow of coolant. These components add bulk and complexity to the system, increasing its size and weight, which can be problematic in applications with strict space or weight constraints. The reliance on external pumps and supplementary equipment also makes it challenging to achieve localized control over the fluid flow rate in each channel. For example, channels that need higher cooling capacity cannot receive additional flow without affecting the entire system, which limits efficiency and adaptability.

Given these limitations, there is a growing need for pump-free thermal regulation systems that can operate without an external pump. Such systems would ideally incorporate local, adaptive micro-pumps or other mechanisms capable of adjusting fluid flow at the individual channel level. By enabling localized control, adaptive micro-pumps would allow each channel to receive fluid based on its unique thermal load, enhancing overall cooling efficiency and responsiveness. This approach not only simplifies the system by eliminating bulky pump components but also provides a highly adaptable solution that can meet the dynamic cooling needs of complex, multi-channel thermal regulation systems. The adaptive feedback loop conserves power and prevents overcooling.

Various embodiments of cooling assemblies and systems that include a microfluidic fiber pump are described in detail herein. Whenever possible, the same reference numerals will be used throughout the drawings to refer to the same or like parts.

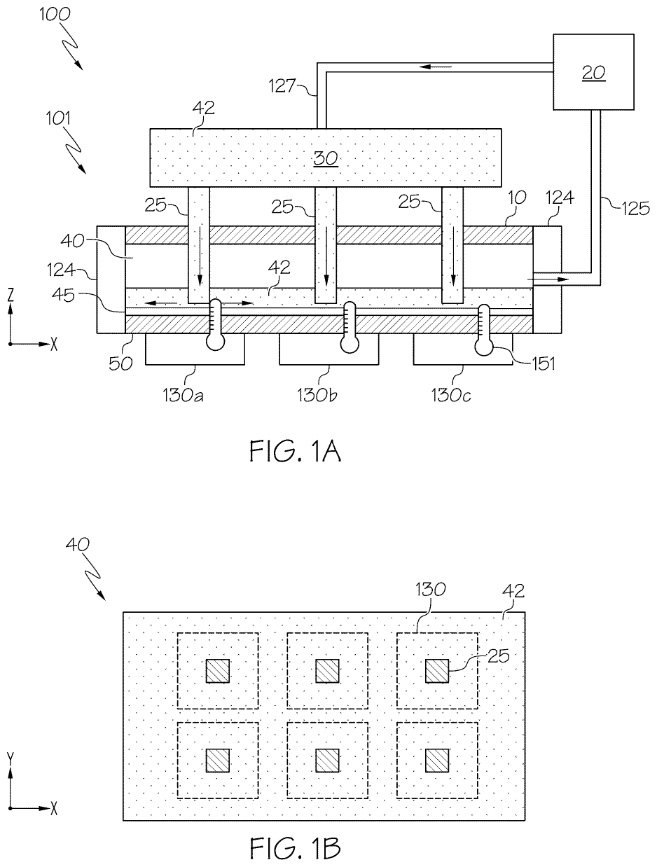

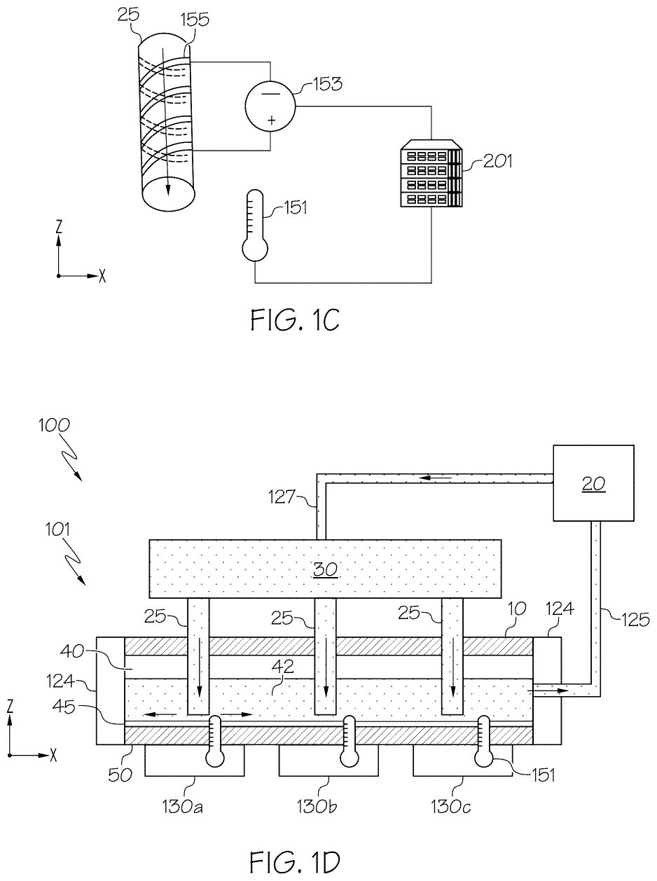

As used herein, the term “device lateral direction” refers to the forward-rearward direction of the device (i.e., in a y-direction of the coordinate axes depicted in FIGS. 1A-1D). The term “device longitudinal direction” refers to the cross-direction of the device (i.e., along the x-axis of the coordinate axes depicted in FIGS. 1A-1D), and is transverse to the lateral direction. The term “device vertical direction” refers to the upward-downward direction of the device (i.e., in the z direction of the coordinate axes depicted in FIGS. 1A-1D). As used herein, “upper” is defined as generally being towards the positive z-axis direction of the coordinate axes shown in the drawings. “lower” or “below” is defined as generally being towards the negative z-axis direction of the coordinate axes shown in the drawings.

As used herein, the singular forms “a,” “an” and “the” include plural referents unless the context clearly dictates otherwise. Thus, for example, reference to “a” component includes aspects having two or more such components unless the context clearly indicates otherwise.

Turning to the figures, FIGS. 1A-1D schematically depict an example microfluidic fiber pump thermal regulation system 100 for thermal management of one or more electronic devices 130. FIG. 1D illustrates a cross-sectional view of the microfluidic fiber pump thermal regulation system 100 working in a single-phase cooling mode and FIG. 1A illustrates a cross-section view of the microfluidic fiber pump thermal regulation system 100 working in a two-phase cooling mode. FIG. 1B illustrates a top view of the microfluidic fiber pump thermal regulation system 100. The microfluidic fiber pump thermal regulation system 100 may include a condenser 20, a fluid reservoir 30, and a housing 101 to form a fluid flow loop. The housing 101 includes one or more substrates 50, a side wall 124, an upper wall 10 positioned opposite of the substrates 50 and spaced apart by the side wall 124 to define a cavity 40. The substrates 50 may be configured to perform heat exchange between coolant 42 in the cavity 40 and one or more heat sources, such as one or more electronic devices 130. In some embodiments, the fluid reservoir 30 may be fluidly coupled to the condenser 20 via a first conduit 127 in an inflow direction, and fluidly coupled to the housing 101 via a plurality of fiber pump jets 25 in an outflow direction. The housing 101 may be fluidly coupled to the condenser 20 via a second conduit 125, and may be configured to be thermally coupled to one or more heat sources subject to thermal regulation, such as the one or more electronic devices 130. The first conduit 125 and/or the second conduit 127 may be a fiber pump tube including one or more pairs of wire electrodes 155. The wire electrodes 155 may be helical. In some embodiments, the cavity 40 may be fluidly coupled to the condenser and each substrate 50 may be configured to be thermally coupled to one of the electronic devices 130. The electronic devices 130 is depicted, without limitation, as electronic devices 130a, 130b, and 130c. This is non-limiting and there may be less than three electronic devices 130 or more than three electronic devices 130. Further, example electronic devices 130 include, without limitation, a heater, a substrate, cold plates, and other semi-conductor devices, that generate a heat load requiring fluid cooling.

The electronic device 130 may be a power device that may include one or more semiconductor devices such as, but not limited to, an insulated gate bipolar transistor (IGBT), a reverse conducting IGBT (RC-IGBT), a metal-oxide-semiconductor field-effect transistor (MOSFET), a power MOSFET, a diode, a transistor, and/or combinations thereof. In some embodiments, the electronic device 130 may include a wide-bandgap semiconductor, and may be formed from any suitable material such as, but not limited to, silicon carbide (SiC), silicon dioxide (SiO2), aluminum nitride (AlN), gallium nitride (GaN), and boron nitride (BN), and the like. In some embodiments, the electronic device 130 may include ultra-wide-bandgap devices formed from suitable materials such as AlGaN/AlN, Ga₂O₃, and diamond. In some embodiments, the electronic device 130 may operate within a power module having a high current and/or a high power and under high temperatures (for example, in excess of 100° C., 150° C., 175° C., 200° C., 225° C., or 250° C.) and dissipate a large amount of power in the form of heat that must be removed for the continued operation of the electronic device 130. As illustrated in FIGS. 1A and 1B, each electronic device 130 may be associated with a fiber pump jet 25 and/or a substrate 50, such that the temperature of each electronic device 130 may be individually tuned through controlling a flow rate of the associated fiber pump jet 25.

In some embodiments, the housing 101 is positioned downstream of the fluid reservoir 30 via the fiber pump jets 25. As illustrated in FIG. 1C, the one or more of the fiber pump jets 25 may include a pair of wire electrodes 155. The microfluidic fiber pump thermal regulation system 100 may include one or more electric sources 153. Each electric source 153 may be electrically coupled to one of the fiber pump jets 25, wherein the electric sources 153 may be configured to individually apply controllable a bias to the wire electrodes 155 of the one or more of the fiber pump jets 25. In some embodiments, the first conduit 127 and/or the second conduit 125 may each similarly include a pair of wire electrodes electrically coupled to one of the electric sources 153. As described in more detail further below, the microfluidic fiber pump thermal regulation system 100 may individually control the bias generated by the electric sources 153 applied to the one or more of the fiber pump jets, the second conduit 125, and/or the first conduit 127 to control a flow direction and a flow rate of liquid coolant 42 that flows within, as depicted by the arrow labeled in FIGS. 1A and 1D, from the fluid reservoir 30, through the fiber pump jets 25, into the cavity 40 of the housing 101, from the cavity 40, through the second conduit 125, to the condenser 20, and from the condenser 20, through the first conduit 127, to the fluid reservoir 30. As such, the fluid flow loop is a closed loop fluid path.

In some embodiments, the liquid coolant 42 may include dielectric cooling fluids such as, without limitation, methoxy-nonafluorobutane, perfluoropolyethers, fluorinated liquids (e.g., perfluorinated alkanes, perfluorinated ethers), silicone-based oil, deionized water, R-245fa, and HFE-7100. Other dielectric or refrigerant cooling fluids may be utilized. The liquid coolant 42 may have a conductivity range from about 10⁻¹² S/m to about 10⁻⁶ S/m, from about 10⁻¹¹ S/m to about 10⁻⁷ S/m, from about 10⁻¹⁰ S/m to about 10⁻⁸ S/m, or any values between about 10⁻¹² S/m to about 10⁻⁶ S/m. The liquid coolant 42 may have a viscosity range from about 1 cPa to about 100 cPa, from about 10 cPa to about 90 cPa, from about 20 cPa to about 80 cPa, from about 30 cPa to about 70 cPa, from about 40 cPa to about 60 cPa, or any values between about 1 cPa and about 100 cPa. The liquid coolant 42 may have a breakdown strength equal to or greater than 10 kV/cm, equal to or greater than 20 kV/cm, equal to or greater than 30 kV/cm, equal to or greater than 40 kV/cm, equal to or greater than 50 kV/cm, equal to or greater than 75 kV/cm, equal to or greater than 100 kV/cm, equal to or greater than 200 kV/cm, equal to or greater than 500 kV/cm, equal to or greater than 1000 kV/cm, or any values above 10 kV/cm. The type of dielectric or refrigerant cooling fluid chosen may depend on the operating temperature of the heat-generating devices to be cooled.

In some embodiments, the housing 101 may include various structures and components, such as, without limitation, a manifold pool, the substrates 50, the side wall 124, the upper wall 10 positioned opposite of the substrates 50 and spaced apart by the side wall 124 to define the cavity 40. In some embodiments, the side walls 124 and the upper wall 10 may be formed as a single continuous wall. For example, the side wall 124 and the upper wall 10 may be formed using additive manufacturing techniques or processes.

As used herein, the terms “additively manufactured” or “additive manufacturing techniques or processes” refer generally to manufacturing processes wherein successive layers of material(s) are provided on each other to “build-up,” layer-by-layer, a three-dimensional component. The successive layers generally fuse together to form a monolithic component which may have a variety of integral sub-components. Although additive manufacturing technology is described herein as enabling fabrication of complex objects by building objects point-by-point, layer-by-layer, typically in a vertical direction, other methods of fabrication are possible and within the scope of the present subject matter. For example, although the discussion herein refers to the addition of material to form successive layers, one skilled in the art will appreciate that the methods and structures disclosed herein may be practiced with any additive manufacturing technique or manufacturing technology. For example, some embodiments may use layer-additive processes, layer-subtractive processes, or hybrid processes.

Suitable additive manufacturing techniques in accordance with the present disclosure include, for example, Fused Deposition Modeling (FDM), Selective Laser Sintering (SLS), 3D printing such as by inkjets and laserjets, Sterolithography (SLA), Direct Selective Laser Sintering (DSLS), Electron Beam Sintering (EBS), Electron Beam Melting (EBM), Laser Engineered Net Shaping (LENS), Laser Net Shape Manufacturing (LNSM), Direct Metal Deposition (DMD), Digital Light Processing (DLP), Direct Selective Laser Melting (DSLM), Selective Laser Melting (SLM), Direct Metal Laser Melting (DMLM), and other known processes.

The additive manufacturing processes described herein may be used for forming components using any suitable material. For example, the material may be plastic, metal, concrete, ceramic, polymer, epoxy, photopolymer resin, or any other suitable material that may be in solid, liquid, powder, sheet material, wire, or any other suitable form. More specifically, according to exemplary embodiments of the present subject matter, the additively manufactured components described herein may be formed in part, in whole, or in some combination of materials including but not limited to pure metals, nickel alloys, chrome alloys, titanium, titanium alloys, magnesium, magnesium alloys, aluminum, aluminum alloys, and nickel or cobalt base superalloys (e.g., those available under the name Inconel® available from Special Metals Corporation). These materials are examples of materials suitable for use in the additive manufacturing processes described herein, and may be generally referred to as “additive materials.”

In some embodiments, the side wall 124 and the upper wall 10 may be individually formed through additive manufacturing processes, or other manufacturing processes, and coupled to one another via fasteners. Example fasteners include, without limitation, bolt and nut, screw, rivet, adhesive, epoxy, weld, sintering, and/or the like. In some embodiments, one or more of the substrates 50 may include an inner surface and an opposite outer surface. The inner surface may face toward an interior surface of the upper wall 10 to define a portion of the cavity 40. The electronic device 130 may be coupled to the outer surface of the substrates 50. In some embodiments, the electronic device 130 may be bonded to portions of the outer surface of the substrates 50 via a thermal interface layer, which may include a thermally conductive bond and may include a DBC (direct bonded copper) substrate, solder, or some other high temperature substrate, bonding material, or method. In some embodiments, the thermal interface layer may be a thermal grease positioned between the outer surface of the substrates 50 and the electronic device 130.

In some embodiments, the housing 101 may include a wick 45 connected to the inner surface of the substrates 50. The wick 45 may include a porous structure that includes an upper surface, an opposite lower surface, a pair of side walls, and a pair of end walls that define a thickness. The wick 45 may be porous such that the liquid coolant 42, such as liquid coolant and/or other fluids, may enter, pass through and, in some embodiments, make contact with, or be fluidly coupled to the inner surface of the substrates 50. The lower surface of the wick 45 may be positioned at or extend from the inner surface of the substrates 50 in the vertical direction (i.e., in the z direction). The wick 45 may be dimensionally sized to match, or be equal to the size of the electronic device 130 coupled to the outer surface of the substrates 50. The wick 45 may be, without limitation, in a rectangular shape, a square shape, a hexagonal shape, an octagonal shape, a circular shape, a triangular shape, and/or the like. As such, the wick 45 may be any shape, size, and/or dimension.

Further, in non-limiting examples, the wick 45 may be formed by a sintered copper (Cu) particle wick, a copper inverse opal wick, a wick formed by sintering stacked meshes, a wick that is laser patterned in Cu or a ceramic, a Cu wick that includes simple capillary grooves in a base material, and the like.

In some embodiments, the wick 45 may be a monolithic single structure formed with the substrates 50 to extend from and be fluidly coupled to an inner surface of the substrate at or near the positioning of the electronic device 130. The wick 45 may be positioned to extend from the inner surface in the vertical direction (i.e., in the z direction). In some embodiments, as depicted in FIGS. 1A and 1D, the wick 45 may be separate from the substrates 50 and is fluidly coupled to the inner surface of the substrates 50. For example, in this embodiment, the wick 45 may be coupled to the inner surface of the substrates 50 via a thermally conductive bond and may include a DBC (direct bonded copper) substrate, solder, or some other high temperature substrate, bonding material, or method.

Further, in some embodiments, the wick 45 may extend in the longitudinal direction (i.e., in the x direction) a length less than portions of the housing 101 that abut with the interior surface of the upper wall 10 to provide one or more vapor outlets such that when the fluid makes contact with, or in close proximately to the substrates 50, which absorbs heat generated at the electronic device 130, the vapor created or generated as part of the cooling process, may be expelled, and further transmitted to the second conduit 125. That is, in operation, the wick 45 can draw the liquid via capillary force where the liquid evaporates to vapor due to the heat from the electronic device 130. In addition, it should be understood that for a given manifold design or configuration, there is a certain amount of flooding that takes place, which results in different operating points where the fluid begins to evaporate.

As illustrated in FIG. 1C, in some embodiments, the one or more of the fiber pump jets 25 may include a pair of wire electrodes 155. The wire electrodes 155 may be associated with, such as embedded in or otherwise disposed on, one or more of the fiber pump jets 25 in a continuous helical pattern around an inner surface of the one or more of the fiber pump jets 25. In some embodiments, one or more pairs of wire electrodes 155 may be electrically coupled to one of the electric sources 153. In some embodiments, some pairs of wire electrodes 155 may be electrically coupled to one or more of the electric sources. The electrodes may be, without limitations, gold, platinum, palladium, silver, copper, titanium, iridium oxide, iron, carbon fiber, conductive polymers, or any suitable conductive materials. One or more pairs of wire electrodes 155 may be configured to move the liquid coolant 42 in the fiber pump jets 25 using charge-injection electrohydrodynamics. The wire electrodes 155 may be spaced with an asymmetric spacing to generate a unidirectional flow to maintain a consistent flow orientation.

In operation, in some embodiments, the electric sources 153 may apply direct current (DC) bias on an associated pair of wire electrodes 155. The electric field applied on the pair of wire electrodes 155 may be from about 0.5 kV/mm to about 10 kV/mm, from about 1 kV/mm to about 9 kV/mm, from about 2 kV/mm to about 8 kV/mm, from about 3 kV/mm to about 7 kV/mm to about 6 kV/mm, from about 4 kV/mm to about 5 kV/mm, or any value below or equal to 10 kV/mm. The bias applied on the electrodes may create negatively charged ions in the liquid coolant 42 that mirage toward the positive electrode and/or positively charged ions in the liquid coolant 42 that mirage toward the negative electrode. As charged ions accept electrons at the negative electrode and move toward the positive electrode, the charged ions displace surrounding liquid molecules and create a net directional flow. The asymmetric spacing of the wire electrodes 155 may cause the flow of the liquid coolant 42 from one direction is greater than the other, creating a consistent flow orientation. Accordingly, the microfluidic fiber pump thermal regulation system 100 may operably control the flow direction by controlling the electric sources 153 to apply the desired polarity of the electric field on the wire electrodes 155. The system 100 may include a controller 201, which may acquire temperature information using the thermal sensor 151 for one or more of the electronic devices 130 and control the flow rate of the associated fiber pump jet 25 by manipulating the bias applied on the associated pair of wire electrodes 155 to perform the individual thermal management for one or more of the electronic device 130.

In operation, in some embodiments, the controller 201 may continuously monitor the temperature of one or more of the electronic device 130 (e.g., electronic devices 130a, 130b, and 130c in FIGS. 1A and 1D) using the thermal sensor 151. When the temperature of an electronic device 130 is below a baseline temperature, the controller 201 may control the associated electric source 153 to apply zero bias or a low bias, causing the applied electric field to the wire electrodes 155 as, without limitation, below 0.001 kV/mm, below 0.005 kV/mm, below 0.01 kV/mm, below 0.05 kV/mm, below 0.1 kV/mm, below 0.5 kV/mm, below 1 kV/mm, below 2 kV/mm, or below 3 kV/mm. The baseline temperature refers to a temperature below which the electronic device 130 can function without negative thermal impact to the electronic device 130. The baseline temperature may be around 25° C. to around 40° C. When the temperature of at least one electrode device 130 reaches a cooling threshold temperature, the controller 201 may control the associated electric source 153 to apply median to high bias, causing an applied electric field to the wire electrodes 155 as, without limitation, greater than 1 kV/mm, greater than 2 kV/mm, greater than 3 kV/mm, greater than 5 kV/mm, greater than 7 kV/mm, or greater than 9 kV/mm. The cooling threshold temperature refers to a temperature above which the electronic device 130 can function but may be negatively thermal damaged due to overheating, or the performance of the electronic device 130 may be negatively impacted. The cooling threshold temperature may be around 30° C. to around 50° C. The controller 201 may adaptively control the flow rate by adjusting the electric field strength applied on the associated wire electrodes 155 to enhance heat dissipation. As such, the microfluidic fiber pump thermal regulation system 100 can adaptively manage the electronic devices 130. For example, if electronic device 130a experiences rapid temperature rise, the associated fiber pump jet 25 can be activated to increase the flow rate only for electronic device 130a, providing targeted cooling where needed without affecting electronic devices 130b and 130c. As temperatures decrease back to baseline temperature, the microfluidic fiber pump thermal regulation system 100 may reduce the fiber pump voltage to return to baseline cooling. The controller 201 may include an operation status module 222. The operation status module 222 may include one or more algorithms to learn the cooling rate and efficiency based on the collected temperature data and applied bias data. The operation status module 222 may further predict a bias applied to an associated electric source in operating the electronic devices 130 based on operation data of the electronic devices 130.

Referring back to FIGS. 1A and 1D, the microfluidic fiber pump thermal regulation system 100 may be operated in the two-phase cooling mode as in FIG. 1A and in the single-phase cooling mode as in FIG. 1D. In the single-phase cooling mode as in FIG. 1D, the fiber pump jet 25 may deliver a cooled liquid coolant 42 from the fluid reservoir to the cavity 40, where the cooled liquid coolant 42 flows to the substrates 50 and absorbs heat from the substrates 50. The cooled liquid coolant 42 may raise its temperature without undergoing a phase change and thus remain in a liquid state. The heated liquid coolant 42 may then be pumped through the second conduit 125, which includes a pair of wire electrodes 155 similar to the fiber pump jet 25 as shown in FIG. 1C, to the condenser 20. The liquid coolant 42 may be cooled back down and flow into the fluid reservoir 30, ready to be recirculated back to the cavity 40 for continued cooling. In the two-phase cooling mode as in FIG. 1A, the microfluidic fiber pump thermal regulation system 100 may operate by leveraging the phase change of the coolant 42 for enhanced heat dissipation. After the fiber pump jets 25 supply the cooled liquid coolant 42 to the cavity 40, the liquid coolant 42 may absorb sufficient heat from the substrate 50 to vaporize, transitioning from liquid phase to gas phase. The vaporized coolant 42 may flow through the second conduit 125 toward the condenser 20. At the condenser 20, the vaporized coolant 42 may cool down and condense back into the liquid phase. The condensed liquid coolant 42 may flow from the condenser 20 to the fluid reservoir 30 through the first conduit 127, driven by gravity or by electrohydrodynamic effect with wire electrodes 155 on the first conduit 127. As such, the cooling cycle is complete.

In some embodiments, the second conduit 125 may include a pair of wire electrodes 155 electrically coupled to one of the one or more electric sources 153. The microfluidic fiber pump thermal regulation system 100 may refrain from applying a bias to the pair of wire electrodes 155 of the second conduit 125 in response to determining that the temperatures of at least one electronic device 130 are equal to or above a boiling point of the liquid coolant 42. The microfluidic fiber pump thermal regulation system 100 may apply a bias to the pair of wire electrodes 155 of the second conduit 125 in response to determining that the temperatures of one or more of the electronic devices 130 is below the boiling point of the liquid coolant 42.

In some embodiments, a switch between the one-phase cooling mode and the second-phase cooling mode is automatic. For example, when a temperature of one of the electronic devices 130 is high and the liquid coolant 42 absorbs sufficient heat to be vaporized, the microfluidic fiber pump thermal regulation system 100 may operate in the two-phase cooling mode. When the temperature of the one of the electronic device 130 drops and the heat absorbed is insufficient to vaporize the liquid coolant 42, the microfluidic fiber pump thermal regulation system 100 may operate in the one-phase cooling mode. In some embodiments, the microfluidic fiber pump thermal regulation system 100 may operate to control the operation mode between the one-phase cooling mode and the two-phase cooling mode. For example, in some embodiments, in viewing insufficient cooled liquid coolant 42 in the fluid reservoir 30 (for example monitored using a liquid level sensor), the microfluidic fiber pump thermal regulation system 100 may reduce the flowrate of one or more of the fiber pump jets 25 and allow the microfluidic fiber pump thermal regulation system 100 to operate under the two-phase cooling mode. In some embodiments, in viewing the level of fluid reservoir 30 is high and the electronic device temperature is modest or low, the microfluidic fiber pump thermal regulation system 100 may operate under the one-phase cooling mode. In some embodiments, the housing 101 may include isolated cavities 40, each cavity 40 associated with one or more electronic devices 130. Each cavity 40 may operate in the one-phase cooling mode or the two-phase cooling mode, leading to a hybrid cooling mode of the microfluidic fiber pump thermal regulation system 100.

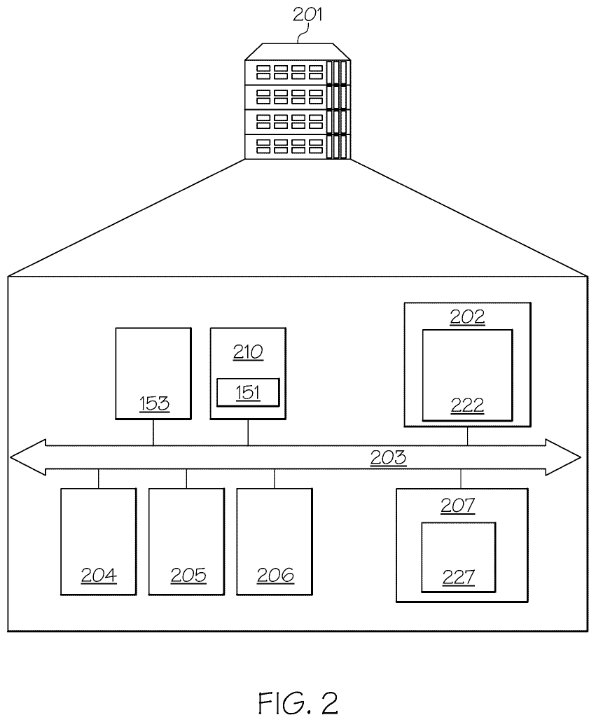

FIG. 2 schematically depicts example components of the microfluidic fiber pump thermal regulation system 100. Microfluidic fiber pump thermal regulation system 100 may include a controller 201. While FIG. 2 depicts one controller 201, more than one controllers 201 may be included in the microfluidic fiber pump thermal regulation system 100. The controller 201 may include one or more memory components 202, a communication path 203, one or more processors 204, input/output hardware 205, network interface hardware 206, a data storage component 207, the electrical property sensor 208 including the thermal sensor 151, and the electric source 153.

The controller 201 may include one or more processors 204. Each of the one or more processors 204 may be any device capable of executing machine-readable and executable instructions. The instructions may be in the form of a machine-readable instruction set stored in data storage component 207 and/or the memory component 202. Accordingly, each of the one or more processors 204 may be a controller, an integrated circuit, a microchip, a computer, or any other computing device. The one or more processors 204 are coupled to a communication path 203 that provides signal interconnectivity between various modules of the system. Accordingly, the communication path 203 may communicatively couple any number of processors 204 with one another, and allow the modules coupled to the communication path 203 to operate in a distributed computing environment. Specifically, each of the modules may operate as a node that may send and/or receive data. As used herein, the term “communicatively coupled” means that coupled components are capable of exchanging data signals with one another such as, for example, electrical signals via a conductive medium, electromagnetic signals via air, optical signals via optical waveguides, and the like.

Accordingly, the communication path 203 may be formed from any medium that is capable of transmitting a signal such as, for example, conductive wires, conductive traces, optical waveguides, or the like. In some embodiments, the communication path 203 may facilitate the transmission of wireless signals, such as WiFi, Bluetooth®, Near Field Communication (NFC), and the like. Moreover, the communication path 203 may be formed from a combination of mediums capable of transmitting signals. In one embodiment, the communication path 203 comprises a combination of conductive traces, conductive wires, connectors, and buses that cooperate to permit the transmission of electrical data signals to components such as processors, memories, sensors, input devices, output devices, and communication devices. Accordingly, the communication path 203 may comprise a vehicle bus, such as for example a LIN bus, a CAN bus, a VAN bus, and the like. Additionally, it is noted that the term “signal” means a waveform (e.g., electrical, optical, magnetic, mechanical, or electromagnetic), such as DC, AC, sinusoidal wave, triangular wave, square-wave, vibration, and the like, capable of traveling through a medium.

The controller 201 may include one or more memory components 202 coupled to the communication path 203. The one or more memory components 202 may comprise RAM, ROM, flash memories, hard drives, or any device capable of storing machine-readable and executable instructions such that the machine-readable and executable instructions can be accessed by the one or more processors 204. The machine-readable and executable instructions may comprise one or more logic or algorithms written in any programming language of any generation (e.g., 1GL, 2GL, 3GL, 4GL, or 5GL) such as, for example, machine language that may be directly executed by the processor, or assembly language, object-oriented programming (OOP), scripting languages, microcode, etc., that may be compiled or assembled into machine-readable and executable instructions and stored on the one or more memory components 202. Alternatively, the machine-readable and executable instructions may be written in a hardware description language (HDL), such as logic implemented via either a field-programmable gate array (FPGA) configuration or an application-specific integrated circuit (ASIC), or their equivalents. Accordingly, the methods described herein may be implemented in any conventional computer programming language, as pre-programmed hardware elements, or as a combination of hardware and software components. The one or more processor 204 along with the one or more memory components 202 may operate as a controller or an electronic control unit (ECU) for the controller 201.

The one or more memory components 202 may include the operation status module 222. The operation status module 222 may include one or more algorithms to learn the cooling rate and efficiency based on the collected temperature data and applied bias data. The operation status module 222 may further predict a bias applied to an associated electric source in operating one or more of the electronic devices 130 based on operation data of the electronic devices 130. The operation status module 222 may be trained and provided with machine learning capabilities via a neural network as described herein. By way of example, and not as a limitation, the neural network may utilize one or more artificial neural networks (ANNs). In ANNs, connections between nodes may form a directed acyclic graph (DAG). ANNs may include node inputs, one or more hidden activation layers, and node outputs, and may be utilized with activation functions in the one or more hidden activation layers such as a linear function, a step function, logistic (Sigmoid) function, a tanh function, a rectified linear unit (ReLu) function, or combinations thereof. ANNs are trained by applying such activation functions to training data sets to determine an optimized solution from adjustable weights and biases applied to nodes within the hidden activation layers to generate one or more outputs as the optimized solution with a minimized error. In machine learning applications, new inputs may be provided (such as the generated one or more outputs) to the ANN model as training data to continue to improve accuracy and minimize error of the ANN model. The one or more ANN models may utilize one-to-one, one-to-many, many-to-one, and/or many-to-many (e.g., sequence-to-sequence) sequence modeling. The one or more ANN models may employ a combination of artificial intelligence techniques, such as, but not limited to, Deep Learning, Random Forest Classifiers, Feature extraction from audio, images, clustering algorithms, or combinations thereof. In some embodiments, a convolutional neural network (CNN) may be utilized. For example, a convolutional neural network (CNN) may be used as an ANN that, in the field of machine learning, for example, is a class of deep, feed-forward ANNs applied for audio analysis of the recordings. CNNs may be shift or space-invariant and utilize shared-weight architecture and translation. Further, each of the various modules may include generative artificial intelligence algorithms. The generative artificial intelligence algorithm may include a general adversarial network (GAN) that has two networks, a generator model and a discriminator model. The generative artificial intelligence algorithm may also be based on variation autoencoder (VAE) or transformer-based models.

The data storage component 207 may store historical operation data 227 and other data related to the phase-change cooling and thermal management of the system. The controller 201 may include the input/output hardware 205, such as, without limitations, a monitor, keyboard, mouse, printer, camera, microphone, speaker, and/or other device for receiving, sending, and/or presenting data. The input/output hardware 205 may include a user interface allowing the user to input or control microfluidic fiber pump thermal regulation system 100 regarding the monitoring and controlling of the phase-change cooling and thermal management.

The controller 201 may include network interface hardware 206 for communicatively coupling the controller 201 to various components of the system and external systems and devices. The network interface hardware 206 can be communicatively coupled to the communication path 203 and can be any device capable of transmitting and/or receiving data via a network. Accordingly, the network interface hardware 206 can include a communication transceiver for sending and/or receiving any wired or wireless communication. For example, the network interface hardware 206 may include an antenna, a modem, LAN port, WiFi card, WiMAX card, mobile communications hardware, near-field communication hardware, satellite communication hardware and/or any wired or wireless hardware for communicating with other networks and/or devices. In one embodiment, the network interface hardware 206 includes hardware configured to operate in accordance with the Bluetooth® wireless communication protocol. The network interface hardware 206 of the controller 201 may transmit its data, e.g., the sensory data collected by the electrical property sensor 208, to the operation status module 222.

The controller 201 may include electrical property sensor 208 coupled to the communication path 203. The electrical property sensor 208 may include, without limitation, the thermal sensor 151 (such as a thermocouple sensor, a heat flux sensor), a pressure sensor, a liquid level sensor, a humidity sensor, a capacitance/impedance sensor, an electric potential/voltage meter, a current meter, a flow rate sensor, a thermo-conductive sensor, or a combination thereof. The electrical property sensor 208 may collect different electrical property data regarding the coolant evaporation and operation of the evaporation apparatus. The electrical property sensor 208 may be wirelessly connected to the controller 201. The controller 201 may include the one or more electric sources 153 coupled to the communication path 203. The electric sources 153 may include an alternating current (AC) power source, such as single-phase AC power or three-phase AC power, a direct current (DC) power source, such as a chargeable battery (e.g., a lithium-ion battery and a nickel-metal hydride battery), a supercapacitor, a solid-state battery, a flywheel energy storage device, or any electric sources suitable for the current application.

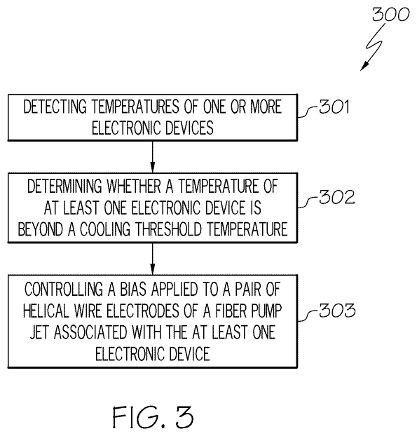

FIG. 3 depicts a flowchart showing illustrative steps for a method 300 of phase-change cooling and thermal management using a microfluidic fiber pump thermal regulation system 100 of the present disclosure. At block 301, the method 300 may include detecting, using one or more thermal sensors, temperatures of one or more electronic devices 130. At block 302, the method 300 may include determining whether a temperature of at least one electronic device 130 is beyond a cooling threshold temperature. At block 303, the method 300 may include in response to determining that the temperature of the at least one electronic device 130 is beyond the cooling threshold temperature, controlling a bias applied to a pair of wire electrodes 155 of a fiber pump jet 25 associated with the at least one electronic device 130 to transfer a liquid coolant flow from a fluid reservoir 30 to a cavity 40 of a housing 101. The biases do not need to be applied to other fiber pump jets and thus only the electronic device 130, the temperature of which is beyond the cooling threshold temperate, is managed to be cooled. The fluid reservoir 30 may be configured to store cooled dielectric liquid, such as the liquid coolant 42. A condenser 20 fluidly may be coupled to the fluid reservoir 30. The housing 101 may include one or more substrates 50, a side wall 124, an upper wall 10 positioned opposite of the substrates 50, and spaced apart by the side wall 124 to define the cavity 40. The cavity 40 may be fluidly coupled to the condenser 20 and one or more of the substrates 50 may be configured to be thermally coupled to one of the electronic devices 130. A plurality of fiber pump jets 25 may be fluidly coupling the fluid reservoir 30 to the housing 101. The one or more of the fiber pump jets 25 may include the pair of wire electrodes 155. One or more electric sources 153 may be electrically coupled to the fiber pump jets 25.

In some embodiments, the microfluidic fiber pump thermal regulation system 100 may further include a second fiber pump tube, such as the second conduit 125, fluidly coupling the cavity 40 to the condenser 20. The second pump tube may include a pair of wire electrodes electrically coupled to one of the one or more electric sources 153. The method 300 may further include refraining from applying a bias to the pair of wire electrodes in response to determining that the temperatures of at least one of the electronic devices 130 are equal to or above a boiling point off the dielectric liquid, such as the liquid coolant 42. The method 300 may further include applying a bias to the pair of wire electrodes in response to determining that the temperatures of the electronic devices 130 are below the boiling point of the dielectric liquid.

In some embodiments, the microfluidic fiber pump thermal regulation system 100 may further include a first fiber pump tube, such as the first conduit 127, fluidly coupling the condenser 20 to the fluid reservoir 30. The first fiber pump tube may include a pair of wire electrodes electrically coupled to one of the electric sources 153. The first fiber pump tube may be configured to transport the cooled dielectric liquid, such as the liquid coolant 42, to the fluid reservoir 30.

In some embodiments, one or more of the pairs of wire electrodes 155 may be embedded in one of the fiber pump jets 25 in a continuous helical pattern around an inner surface of the one or more of the fiber pump jets 25. One or more of the pairs of wire electrodes 155 may be asymmetrically spaced. One or more of the pairs of wire electrodes 155 may be configured to move the dielectric liquid, such as the liquid coolant 42, in the fiber pump jets 25 using charge-injection electrohydrodynamics

In some embodiments, the dielectric liquid, such as the liquid coolant 42, may have a conductivity range from about 10⁻¹² S/m to about 10⁻⁶ S/m, a viscosity range from about 1 cPa to about 100 cPa, and a breakdown strength equal to or greater than 10 kV/cm. The dielectric liquid may include methoxy-nonafluorobutane, perfluoropolyethers, fluorinated liquids, silicone-based oil, or a combination thereof.

Accordingly, the embodiments described herein are directed to a microfluidic fiber pump thermal regulation system that includes fiber pump tubes fuidling coupling a fluid reservoir to a cooling chamber of a housing having one or more substrates thermally coupled to one or more heat sources. The fiber pump tubes may includes wire electrodes to utilize charge-injection electrohydrodynamics and can be adaptively controlled to transfer coolant to the one or more substrates to selectively thermally control the one or more heat sources, such as the electronic devices.

It is noted that the terms “substantially” and “about” may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

1. A cooling assembly for thermal management of one or more electronic devices, comprising:
a fluid reservoir configured to store a dielectric liquid;
a condenser fluidly coupled to the fluid reservoir;
a housing comprising one or more substrates, a side wall, an upper wall positioned opposite of the substrates and spaced apart by the side wall to define a cavity, the cavity fluidly coupled to the condenser, and one or more of the substrates configured to be thermally coupled to one or more of the electronic devices;
a plurality of fiber pump jets fluidly coupling the fluid reservoir to the housing, one or more of the fiber pump jets comprising one or more pairs of wire electrodes; and
one or more electric sources electrically coupled to one of the fiber pump jets, wherein the electric sources are configured to individually apply a controllable bias to the wire electrodes of one or more fiber pump jets to control a flow rate of the dielectric liquid from the fluid reservoir to the cavity in the one or more fiber pump jets.

2. The cooling assembly of claim 1, wherein the cooling assembly further comprises a first fiber pump tube fluidly coupling the condenser to the fluid reservoir.

3. The cooling assembly of claim 2, wherein the first fiber pump tube comprises a pair of wire electrodes electrically coupled to one of the electric sources, the first fiber pump tube configured to transport the cooled dielectric liquid to the fluid reservoir.

4. The cooling assembly of claim 1, wherein the cooling assembly further comprises a second fiber pump tube fluidly coupling the cavity to the condenser.

5. The cooling assembly of claim 4, wherein the second fiber pump tube is configured to transport a vapor transformed from the dielectric liquid by absorbing heat from the substrate above a boiling point of the dielectric liquid.

6. The cooling assembly of claim 4, wherein the second fiber pump tube comprises a pair of wire electrodes electrically coupled to one of the one or more electric sources, the second fiber pump tube configured to transport the dielectric liquid after absorbing heat from the substrates below a boiling point of the dielectric liquid.

7. The cooling assembly of claim 1, wherein the cooling assembly further comprises one or more thermal sensors configured to monitor temperatures of the electronic devices.

8. The cooling assembly of claim 7, wherein the electric sources are configured to individually apply the controllable bias to the wire electrodes of the one or more of the fiber pump jets based on the temperature of the electronic devices.

9. The cooling assembly of claim 1, wherein one or more of the pairs of wire electrodes are embedded in one of the fiber pump jets in a continuous helical pattern around an inner surface of one or more of the fiber pump jets.

10. The cooling assembly of claim 1, wherein one or more of the pairs of wire electrodes are configured to move the dielectric liquid in the fiber pump jets using charge-injection electrohydrodynamics.

11. The cooling assembly of claim 1, wherein one or more of the pairs of wire electrodes are asymmetrically spaced.

12. The cooling assembly of claim 1, wherein the dielectric liquid has a conductivity range from about 10⁻¹² S/m to about 10⁻⁶ S/m, a viscosity range from about 1 cPa to about 100 cPa, and a breakdown strength equal to or greater than 10 kV/cm.

13. The cooling assembly of claim 1, wherein the dielectric liquid comprises methoxy-nonafluorobutane, perfluoropolyethers, fluorinated liquids, silicone-based oil, or a combination thereof.

14. A cooling system for thermal management of one or more electronic devices, comprising:
a fluid reservoir configured to store a dielectric liquid;
a condenser fluidly coupled to the fluid reservoir;
a housing comprising one or more substrates, a side wall, an upper wall positioned opposite of the substrates and spaced apart by the side wall to define a cavity, the cavity fluidly coupled to the condenser and one or more of the substrate configured to be thermally coupled to one or more of the electronic devices;
a plurality of fiber pump jets fluidly coupling the fluid reservoir to the housing, one or more of the fiber pump jets comprising one or more pairs of wire electrodes;
one or more electric sources, one or more of the electric sources electrically coupled to one of the fiber pump jets;
one or more thermal sensors configured to monitor temperatures of the electronic devices; and
one or more processors, the processors operable to, based on the temperatures of the electronic devices, control a flow rate of the dielectric liquid from the fluid reservoir to the cavity in the one or more of the fiber pump jets by controlling a bias applied to the wire electrodes of the one or more of the fiber pump jets.

15. The cooling system of claim 14, wherein
the cooling system further comprises a second fiber pump tube fluidly coupling the cavity to the condenser, the second fiber pump tube comprising a pair of wire electrodes electrically coupled to one of the one or more electric sources; and
the one or more processors are operable to:
refrain from applying the bias to the pair of wire electrodes in response to determining that the temperatures of at least one of the electronic devices are equal to or above a boiling point of the dielectric liquid; and
apply the bias to the pair of wire electrodes in response to determining that the temperatures of the electronic devices are below the boiling point of the dielectric liquid.

16. The cooling system of claim 14, wherein the cooling system further comprises a first fiber pump tube fluidly coupling the condenser to the fluid reservoir, the first fiber pump tube comprising a pair of wire electrodes electrically coupled to one of the electric sources, the first fiber pump tube configured to transport the cooled dielectric liquid to the fluid reservoir.

17. The cooling system of claim 14, wherein one or more of the wire electrodes are embedded in one of the fiber pump jets in a continuous helical pattern around an inner surface of the one or more of the fiber pump jets, and one or more of the wire electrodes are asymmetrically spaced.

18. A method for thermal management of one or more electronic devices, comprising:
detecting, using one or more thermal sensors, temperatures of the one or more electronic devices;
determining whether a temperature of at least one electronic device is beyond a cooling threshold temperature;
in response to determining that the temperature of the at least one electronic device is beyond the cooling threshold temperature, controlling a bias applied to a pair of wire electrodes of a fiber pump jet associated with the at least one electronic device to transport a dielectric liquid from a fluid reservoir to a cavity of a housing comprising a substrate thermally coupled to the at least one electronic device; and
wherein:
the fluid reservoir is fluidly coupled to a condenser;
the housing comprises one or more substrates, a side wall, an upper wall positioned opposite of the substrates and spaced apart by the side wall to define the cavity, the cavity fluidly coupled to the condenser, and one or more of the substrates thermally coupled to one of the electronic devices;
a plurality of fiber pump jets are fluidly coupling the fluid reservoir to the housing, one or more of the fiber pump jets comprising one or more pairs of wire electrodes; and
one or more electric sources electrically coupled to one or more of the fiber pump jets.

19. The method of claim 18, wherein
a first fiber pump tube is fluidly coupling the condenser to the fluid reservoir;
a second fiber pump tube is fluidly coupling the cavity to the condenser, wherein the second fiber pump tube comprises a pair of wire electrodes electrically coupled to one of the one or more electric sources; and
the method further comprises:
refraining from applying the bias to the pair of wire electrodes in response to determining that the temperatures of at least one of the electronic devices are equal to or above a boiling point off the dielectric liquid; and
applying the bias to the pair of wire electrodes in response to determining that the temperatures of the electronic devices are below the boiling point of the dielectric liquid.

20. The method of claim 18, wherein one or more of the wire electrodes are embedded in one of the fiber pump jets in a continuous helical pattern around an inner surface of the one or more of the fiber pump jets, and one or more of the wire electrodes are asymmetrically spaced.
